(19) United States
(12) Patent Application Publication
(10) Pub. No.: US 2025/0227976 A1
(43) Pub. Date: Jul. 10, 2025

(54) SEMICONDUCTOR DEVICE AND METHOD OF FABRICATING THE SAME

(71) Applicant: United Semiconductor (Xiamen) Co., Ltd., Xiamen (CN)

(72) Inventors: Yong XIE, Shamen City (CN); Sheng-Hsu LIU, Changhua County (TW); Qiang GAO, Shamen City (CN); Shih-Hsien HUANG, Kaohsiung City (TW); Wen Yi TAN, Xiamen (CN)

(73) Assignee: United Semiconductor (Xiamen) Co., Ltd., Xiamen (CN)

(21) Appl. No.: 18/433,416

(22) Filed: Feb. 6, 2024

(30) Foreign Application Priority Data
Jan. 10, 2024 (CN) 202410038649.6

(51) Int. Cl. H01L 29/66; H01L 29/78; H10B 10/00

(52) U.S. Cl. CPC H10D 64/021; H10B 10/12; H10D 30/6215; H10D 64/015; H10D 64/017

(57) ABSTRACT

The present disclosure provides a semiconductor device including a substrate, two gate structures, a spacer structure, an epitaxial structure, a capping structure and a metal silicide layer. The two gate structures are disposed on the substrate. The spacer structure is disposed on the substrate and surrounds each of the gate structures. The epitaxial structure is disposed in the substrate, between the two gate structures. The capping structure is disposed on the epitaxial structure, between the two gate structures. The metal silicide layer is disposed on the capping structure. The spacer structure includes a first spacer, a second spacer and a third spacer stacked sequentially on a sidewall of each of the gate structures, and the second spacer at least contacts a partial sidewall of the capping structure.

### BACKGROUND OF THE INVENTION

### 1. Field of the Invention

The present disclosure relates generally to a semiconductor device and a method of fabricating the same, and more particularly to a semiconductor device having an epitaxial structure and a method of fabricating the same.

### 2. Description of the Prior Art

For the sake of increasing the carrier mobility of the semiconductor structure, a compressive stress or tensile stress can be optionally applied to the gate channel. In conventional arts, a selective epitaxial growth (SEG) process is used to form a compressive stress. For example, after the formation of a gate on a silicon substrate, a silicon-germanium (SiGe) epitaxial structure is formed in the predetermined location, in which the lattice arrangement of silicon (Si) and germanium (Ge) are similar to each other. Since the lattice constant of the SiGe layer is larger than a lattice constant of Si, accordingly, the band structure of Si may be changed, and the compressive stress is then formed and applied to the channel region of a PMOS transistor, thereby increasing the carrier mobility in the channel region, as well as increasing the efficiency of the PMOS transistor. On the other hand, a silicon carbide (SiC) epitaxial structure can also be optionally formed in the silicon substrate of a NMOS transistor, to apply the tensile stress to the channel region of the NMOS transistor. However, although the above method can effectively improve the carrier mobility in the channel region, the processing limits of fabrication are dramatically increased as the semiconductor device is increasingly miniaturized. Thus, how to resolve the issue both in the structure and the fabrication for the semiconductor device has become an important task in this field, so as to gain a device with better reliability.

### SUMMARY OF THE INVENTION

An object of the present disclosure is to provide a semiconductor device and a method of fabricating thereof, where the aspect ratio between a thickness of a capping structure and a minimum distance from the capping structure to a gate structure has been precisely controlled through arranging a spacer structure. Accordingly, it is sufficient to improve the electrical performance of the semiconductor device, and to gain a semiconductor structure with optimized operation.

To achieve the above object, the present disclosure provides a semiconductor device including a substrate, two gate structures, a spacer structure, an epitaxial structure, a capping structure and a metal silicide layer. The two gate structures are disposed on the substrate. The spacer structure is disposed on the substrate and surrounds each of the gate structures. The epitaxial structure is disposed in the substrate, between the two gate structures. The capping structure is disposed on the epitaxial structure, between the two gate structures. The metal silicide layer is disposed on the capping structure. The spacer structure includes a first spacer, a second spacer and a third spacer stacked sequentially on a sidewall of each of the gate structures, and the second spacer at least contacts a partial sidewall of the capping structure.

To achieve the above object, the present disclosure provides a method of fabricating a semiconductor device including the following steps. Firstly, a substrate is provided, and two gate structures are formed on the substrate. A first spacer and a dummy spacer are sequentially formed on the substrate, to surround the two gate structures. An epitaxial structure is formed in the substrate, between the two gate structures. A capping structure is formed on the epitaxial structure, between the two gate structures, wherein the capping structure includes a first capping layer and a second capping layer stacked sequentially on the epitaxial structure. A metal silicide layer is formed on the capping structure, wherein forming the capping structure further includes forming the first capping layer, forming a capping material layer on the first capping layer, oxidizing a portion of the capping material layer, and removing an oxidized portion of the capping material layer, to form the second capping layer stacked on the first capping layer.

Overall speaking, according to the semiconductor device of the present disclosure, a second spacer is arranged between the gate structure and the capping structure and/or the epitaxial structure, to at least partially contact the capping structure, such that, the aspect ratio between the thickness of the capping structure and the distance from the capping structure to the gate structure will be precisely controlled, to prevent a current-intensive regions at two sides of the gate structure from being affected by the capping structure and/or the epitaxial structure, thereby improving the electrical performance of the semiconductor device, and further improving the operation of the semiconductor device. Through these arrangements, the semiconductor device of the present disclosure is allowable to be put in use on any functional semiconductor device including the epitaxial structure, such as a metal-oxide semiconductor (MOS) transistor device or a static random access memory device (SRAM) device, but not limited thereto.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a cross-sectional view of a semiconductor device according to a first embodiment in the present disclosure.

FIG. 2 is a schematic diagram illustrating a top view of a semiconductor device according to a preferable embodiment in the present disclosure.

FIG. 3 to FIG. 6 are schematic diagrams illustrating a method of fabricating a semiconductor device according to a first embodiment in the present disclosure, in which:

FIG. 3 illustrates a cross-sectional view of a semiconductor device after forming a capping structure;

FIG. 4 illustrates a cross-sectional view of a semiconductor device after performing a thermal oxidation process;

FIG. 5 illustrates a cross-sectional view of a semiconductor device after forming a second spacer; and

FIG. 6 illustrates a cross-sectional view of a semiconductor device after forming a spacer structure.

FIG. 7 and FIG. 8 are schematic diagrams illustrating a method of fabricating a semiconductor device according to a second embodiment of the present disclosure, in which:

FIG. 7 illustrates a cross-sectional view of a semiconductor device after forming a second spacer; and

FIG. 8 illustrates a cross-sectional view of a semiconductor device after forming a metal silicide layer.

FIG. 9 and FIG. 10 are schematic diagrams illustrating a method of fabricating a semiconductor device according to a third embodiment of the present disclosure, in which:

FIG. 9 illustrates a cross-sectional view of a semiconductor device after removing a dummy spacer; and

FIG. 10 illustrates a cross-sectional view of a semiconductor device after forming a metal silicide layer.

### DETAILED DESCRIPTION

To provide a better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

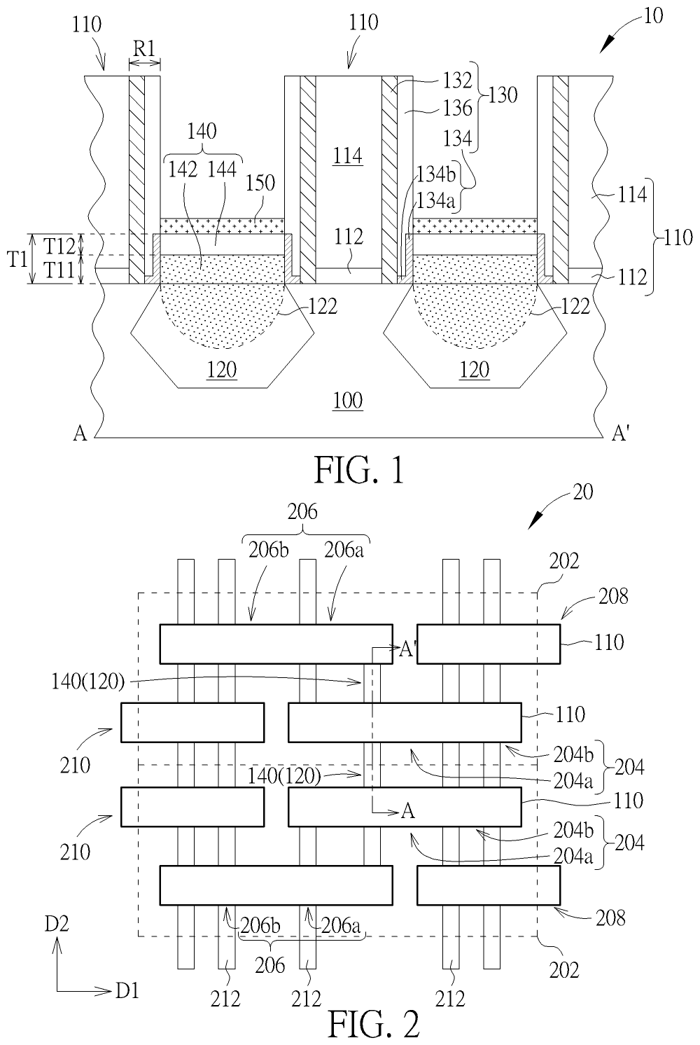

Please refer to FIG. 1, which illustrates a cross-sectional view of a semiconductor device 10 according to a first embodiment of the present disclosure. The semiconductor device 10 includes a substrate 100, two gate structures 110, an epitaxial structure 120, a spacer structure 130, a capping structure 140, and a metal silicide layer 150. The substrate 100 for example includes a silicon substrate, an epitaxial silicon substrate, a silicon containing substrate or a silicon-on-insulator (SOI) substrate, but not limited thereto. In one embodiment, the substrate 100 further includes a plurality of fin shaped structure (not shown in the drawings) disposed therein, to serve as a non-planar substrate, but not limited thereto. The two gate structures 110 are separately disposed on the substrate 100, and each includes a gate dielectric layer 112 and a gate layer 114 stacked sequentially on a top surface of the substrate 100. In one embodiment, the gate dielectric layer 112 for example includes a dielectric material like silicon oxide, and the gate layer 114 for example includes a semiconductor material like doped polysilicon or doped amorphous silicon, but not limited thereto. The spacer structure 130 is also disposed on the substrate 100, to surround each of the gate structures 110 respectively. The epitaxial structure 120 is disposed within the substrate 100, between the two gate structures 110, and the capping structure 140 is disposed on the epitaxial structure 120, also between the two gate structures 110. The metal silicide layer 150 is disposed on the capping structure 140.

It is noted that, the spacer structure 130 precisely includes a first spacer 132, a second spacer 134, and a third spacer 136 stacked sequentially on a sidewall of each of the gate structures 110. The second spacer 134 for example includes a sidewall being vertically aligned with a sidewall of the third spacer 136, such that, the second spacer 134 will directly contacts a sidewall of the capping structure 140. Accordingly, through arranging the second spacer 134 of the spacer structure 130 between the first spacer 132 and the capping structure 140, an aspect ratio between a thickness T1 of the capping structure 140 and a minimum distance R1 from the capping structure 140 to one gate structure 110 can be precisely controlled between 1 and 3, preferably being between 1.2 and 2.2, but not limited thereto. With these arrangements, the distance R1 from the gate structure 110 to the capping structure 140 and/or the epitaxial structure 120 may be effectively enlarged, to prevent a current-intensive regions at two sides of the gate structure 110 from being affected by the capping structure 140 and/or the epitaxial structure 120, thereby improving the electrical performance of the semiconductor device 10, and further improving the operation of the semiconductor device 10.

Precisely speaking, the second spacer 134 for example includes a L-shaped cross-section, wherein a vertical portion 134a of the L-shaped cross-section overlays the entire sidewall of the capping structure 140 to vertically align with the sidewall of the third spacer 136, and a horizontal portion 134b of the L-shaped cross-section overlays the top surface of the substrate 100. In one embodiment, the first spacer 132, the second spacer 134, and the third spacer 136 for example include different dielectric materials respectively, such as including silicon oxide, silicon nitride, silicon carbonitride or silicon oxynitride, and the second spacer 134 preferably includes a material having an etching selectivity related to that of the first spacer 132 and the third spacer 136, but not limited thereto. People skilled in the art should fully understand that although the first spacer 132, the second spacer 134, and the third spacer 136 are exemplified by having a monolayer structure as shown in FIG. 1, the practical structures thereof are not limited thereto, and which may optionally include a multilayer structure due to product requirements.

Further in view of FIG. 1, the epitaxial structure 120 is formed for example along a specific lattice plane, to obtain a cross-section in various shapes, such as in diamond, hexagon (also known as sigma 2) or octagon shape, but not limited thereto. The semiconductor device 10 further includes a doped region 122 disposed in the epitaxial structure 120, to serve as a source/drain region. In one embodiment, the material of the epitaxial structure 120 may be adjusted according to the type of a MOS transistor formed in the subsequent process, for example including a material like silicon germanium (SiGe) or silicon carbide (SiC), and preferably including SiGe, boron germanium silicide (SiGeB) or tin germanium silicide (SiGeSn), but not limited thereto. The material of the doped region 122 may also be adjusted according to the type of the MOS transistor formed in the subsequent process, for example including a P-type dopant or a N-type dopant, but is not limited thereto.

On the other hand, the capping structure 140 precisely includes a first capping layer 142 and a second capping layer 144 stacked sequentially on the epitaxial structure 120. In one embodiment, the first capping layer 142 and the second capping layer 144 for example includes different epitaxial materials respectively, and which optionally include a monolayer structure or a multilayer structure. The first capping layer 142 for example includes doped SiGe, with the germanium atoms disposed therein being altered in a gradual arrangement, and with the surface of the first capping layer 142 preferably having a relative lighter concentration or no germanium at all. The second capping layer 144 for example includes a semiconductor material like silicon, but is not limited thereto. Accordingly, the arrangement of the capping structure 140 enables to facilitate the subsequent formation of the metal silicide layer 150 over the capping structure 140. The first capping layer 142 and the second capping layer 144 for example include different thickness T11, T12, wherein the thickness T11 of the first capping layer 142 is for example about 30 angstroms to 150 angstroms, and the thickness T12 of the second capping layer 144 is for example about 130 angstroms to 210 angstroms, but not limited thereto.

Through the semiconductor device 10 according to the first embodiment of the present disclosure, the second spacer 134 is disposed between the gate structure 110 and the capping structure 140 and/or the epitaxial structure 120, to directly contact the capping structure 140, with the second spacer 134 for example including the L-shaped cross-section. Accordingly, the semiconductor device 10 enables to precisely control the aspect ratio between the thickness T1 of the capping structure 140 and the distance R1 from the capping structure 140 to the gate structure 110 through disposing the second spacer 134, so as to prevent a current-intensive regions at two sides of the gate structure 110 from being affected by the capping structure 140 and/or the epitaxial structure 120, thereby improving the electrical performance of the semiconductor device 10, and further improving the operation of the semiconductor device 10. In this way, the semiconductor device 10 of the present disclosure may be further applied on any functional semiconductor device including the epitaxial structure, such as a MOS transistor device, or a SRAM device, but not limited thereto.

For example, as shown in FIG. 2, a SRAM device 20 is provided and includes a plurality of six-transistor static-random access memory (6T-SRAM) cells 202. Each of the 6T-SRAM cells 202 further includes a first inverter 204, a second inverter 206, and two N-type transistors 208, 210, wherein the two N-type transistors 208, 210 for example include a first pass-gate (PG) transistor 208 and a second pass-gate transistor 210. The first inverter 204 and the second inverter 206 respectively includes two P-type transistors 204a/206a, 204b/206b for example being a first pull-up (PU) transistor 204a and a first pull-down (PD) transistor 206, and a second pull-up transistor 206a and a second pull-down transistor 206b. It is noted that, each of the above-mentioned transistors includes a gate structure 110 extending in a first direction D1 across at least one fin shaped structure 212 extending in a second direction D2 over the substrate 100. Also, the above-mentioned epitaxial structure 120 and the capping structure 140 are further formed within the fin shaped structure 212, at two opposite sides of each gate structure 110 in the second direction D2. Then, people skilled in the art should easily understand that the semiconductor device 10 as shown in FIG. 1 may be a cross-sectional view taken along a cross line A-A′ in FIG. 2, such that, a distance between two adjacent transistors (for example the first PU transistor 204a and the second PU transistor 206a) to the epitaxial structure 120 and/or the capping structure 140 disposed therebetween may be precisely controlled, to prevent the currents on both sides of the gate structures 110 from being influenced by the capping structure 140 and/or the epitaxial structure 120, which is damage to the operation of the SRAM cells 202.

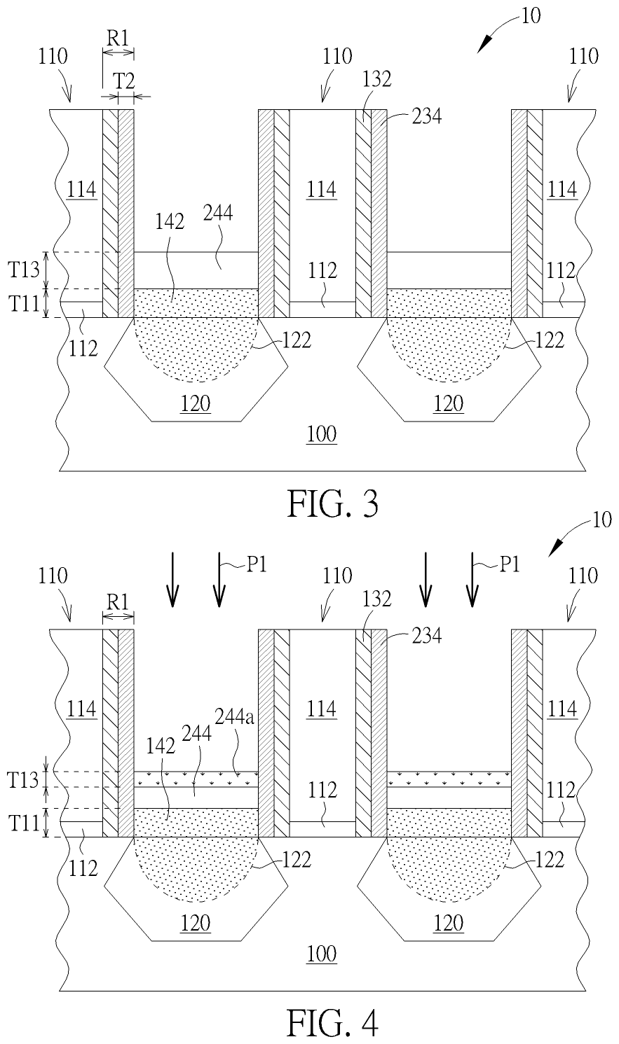

In order to make people skilled in the art of the present disclosure easily understand the semiconductor device 10 of the present disclosure, a fabricating method of the semiconductor device 10 in the present disclosure will be further described below. Please refer to FIG. 3 to FIG. 6, which illustrate a method of fabricating a semiconductor device 10 according to the first embodiment of the present disclosure.

Firstly, as shown in FIG. 3, the substrate 100 is provided, for example being a silicon substrate, an epitaxial silicon substrate, a silicon containing substrate (such as a SiGe substrate or a SiC substrate) or a silicon-on-insulator (SOI) substrate, and a plurality of the gate structures 110 are next formed on the substrate 100. In one embodiment, at least one fin shaped structure (not shown in the drawings) may be previously formed on the substrate 100 through a photolithography process or a multi-patterning process, followed by forming the gate structures 110 on the at least one fin shaped structure. The formation of the at least one fin shaped structure includes but not limited to the following steps. Firstly, a patterned mask (not shown in the drawings) is formed on the substrate, and an etching process is performed through the patterned mask, to form at least one trench (not shown in the drawings) in the substrate, and then the patterned mask is removed. After that, an insulating material is filled in the at least one trench, such that, the substrate 110 partially protrude from the insulating material will therefore serve as the at least one fin shaped structure, and the insulating material will therefore form a shallow trench isolation (not shown in the drawings).

Each of the gate structures 110 precisely includes the gate dielectric layer 112 and the gate layer 114 stacked sequentially on the substrate 100. In one embodiment, the formation of the gate structure 110 includes but not limited to the following steps. A dielectric material layer (not shown in the drawings) for example including a dielectric material like silicon oxide, and a gate material layer (not shown in the drawings) for example including a semiconductor material like doped polysilicon or doped amorphous silicon are sequentially formed on the substrate 100, and the aforementioned material layers stacked on the substrate 100 are next patterned to form the gate structures 110. People skilled in the arts should fully realize that the gate structures 110 of the present disclosure may also be formed through other processes, or have other types. For example, in another embodiment, the gate structure 110 may optionally include a metal gate structure (not shown in the drawings), for example at least including a word function layer (not shown in the drawings) and metal gate (not shown in the drawings) stacked sequentially on the substrate 100.

Then, at least one deposition process and an etching back process are performed, to form a first spacer 132 and a dummy spacer 234 sequentially on the substrate 100, to surround each of the gate structures 110. Then, the epitaxial structure 120 is formed in the substrate 100, at two sides of each of the gate structures 110. The first spacer 132 and the dummy spacer 234 may optionally include a monolayer structure or a multilayer structure, and preferably include dielectric materials having etching selectivity related to each other, such as silicon oxide, silicon nitride, silicon carbonitride, or silicon oxynitride, but not limited thereto. It is noted that, a thickness T2 of the dummy spacer 234 may be further adjustable based on a predict distance R1 between the gate structure 110 and the capping structure 140 formed subsequently, for example being about 150 angstroms to 200 angstroms, but not limited thereto. In one embodiment, the formation of the epitaxial structure 120 includes but not limited to the following steps. Firstly, after forming the first spacer 132 and the dummy spacer 234, an etching process for example a wet etching process, a dry etching process, or a sequentially performed a dry etching process and a wet etching process, is performed on the substrate 100 by using the gate structures 110, the first spacer 132 and the dummy spacer 234 as an etching mask, to form a recess (not shown in the drawings) in the substrate 100 at two sides of each of the gate structures 100. Next, a selective epitaxial growth (SEG) process is performed, to form the epitaxial structure 120 in the recess.

Precisely speaking, the epitaxial structure 120 is formed through a specific lattice plane in the substrate 100, such that, a top surface of the epitaxial structure 120 may be coplanar with the top surface of the substrate 100, and preferably includes a cross-section in various shapes, such as in diamond, hexagon or octagon shape, but not limited thereto. In one embodiment, the epitaxial structure 120 may include various material according to the conductive type of the MOS transistor formed in the subsequent process. For example, if a P-type MOS transistor will be formed, the epitaxial structure 120 for example includes SiGe, SiGeB, or SiGeSn, or if a N-type MOS transistor will be formed, the epitaxial structure 120 for example includes SiC, SiCP, or SiP, but not limited thereto. In another embodiment, the SEG process may also be carried out through a single or a multiple layer approach, and the heterogeneous atoms (such as germanium or carbon atoms) may also be altered in a gradual arrangement.

Following these, an ion implantation process is performed by using the gate structures 110, the first spacer 132 and the dummy spacer 234 as a mask, to form the doped region 122 in at least a portion of the epitaxial structure 120, thereby serving as the source/drain region. The doped region 122 may also include various dopants according to the conductive type of the MOS transistor formed in the subsequent process, for example including P-type dopants or N-type dopants, but not limited thereto. Also, the dopants of the doped region 122 may also be altered in a gradual arrangement. In one embodiment, the formation of the doped region 122 may also be in-situ formed while performing the SEG process. For example, if a P-type MOS transistor will be formed, the epitaxial structure 120 including SiGe, SiGeB or SiGeSn may be doped in-situ with P type dopants to form a P⁺ epitaxial structure thereby. Alternately, if a N-type MOS transistor will be formed, the epitaxial structure 120 including SiC, SiCP or SiP may be doped in-situ with N type dopants to form a N⁺ epitaxial structure thereby. Then, the ion implantation process may be omitted to simplify the process flow of the fabricating method of the present disclosure.

Then, as shown in FIG. 3, another SEG process is performed by further using the gate structures 110, the first spacer 132, and the dummy spacer 234 as a mask, to sequentially from the first capping layer 142 and a capping material layer 244 on the epitaxial structure 120. The first capping layer 142 and the capping material layer 244 for example include different epitaxial materials, and which may optionally include a monolayer structure or a multilayer structure. For example, the first capping layer 142 for example includes a doped SiGe, and the capping material layer 244 for example includes a semiconductor material like silicon, but not limited thereto. It is noted that the capping material layer 244 preferably includes a relative greater thickness T13, for example being about 140 angstroms to 250 angstroms, with the thickness T13 being greater than the thickness T11 of the first capping layer 142 (being about 30 angstroms to 150 angstroms), but not limited thereto.

As shown in FIG. 4, a selective thermal oxidation process P1 such as a rapid thermal oxidation (RTO) process is performed through a mask layer (not shown in the drawings), to consume and to oxidize the top portion of the capping material layer 244 to form a sacrificial layer 244a. It is also noted that, a thickness T3 of the sacrificial layer 244a may be further adjustable based on the entire thickness of the capping structure 140 formed in the subsequent process, for example being about 10 angstroms to 40 angstroms, but not limited thereto. Then, the mask layer is completely removed. In one embodiment, the RTO process is carried out by introducing oxygen under a temperature of about 700° C. to 900° C., but not limited thereto.

As shown in FIG. 5, at least one etching process P21 is performed, to remove the sacrificial layer 244a. That is, a remain portion of the capping material layer 244 becomes the second capping layer 144 with the thickness T12, wherein the thickness T12 of the second capping layer 144 is smaller than the thickness T13 of the original capping material layer 144, and is greater than the thickness T11 of the first capping layer 142. In this way, the first capping layer 142 and the second capping layer 144 stacked sequentially on the epitaxial structure 120 together form the capping structure 140 with the thickness T1. On the other hand, at least a portion of the dummy spacer 234 is removed through the at least one etching process P21, to form the second spacer 134. In the present embodiment, a portion of the dummy spacer 234 is sandwiched between the first spacer 132 and the capping structure 140, without directly contacting the etchant, such that, the dummy spacer 234 overlaying the sidewall of the capping structure 140 and/or the dummy spacer 234 overlaying the top surface of the substrate 100 are partially remained to form the vertical portion 134a and the horizontal portion 134b of the second spacer 134. With these arrangements, the second spacer 134 will therefore obtain the L-shaped cross-section and directly contact the capping structure 140, to maintain the distance R1 from the capping structure 140 to the gate structure 110.

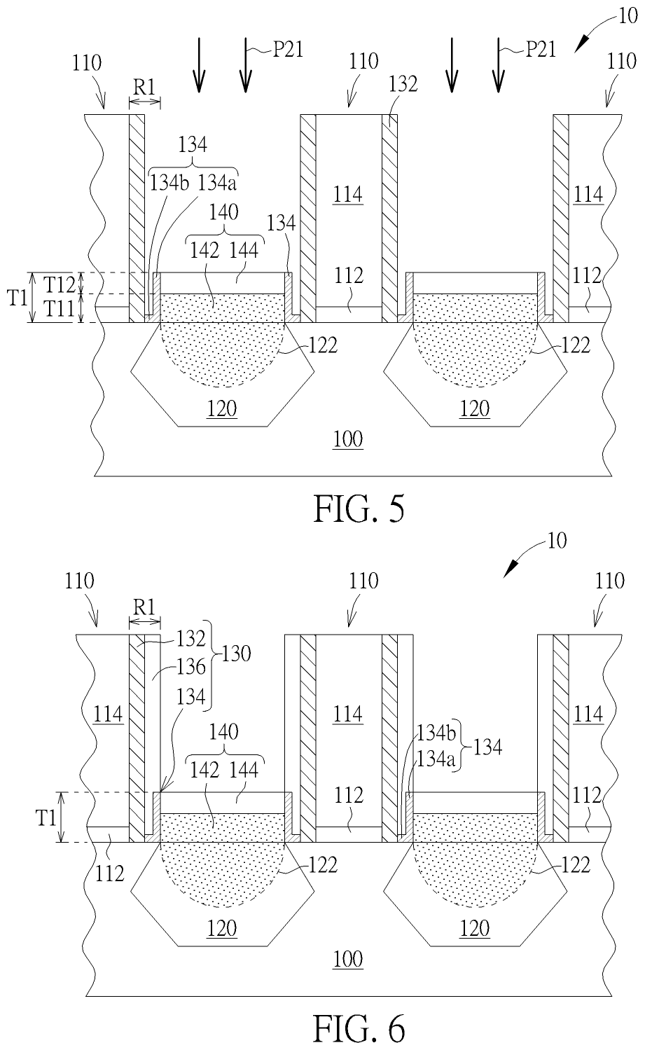

As shown in FIG. 6, a deposition process and an etching back process are sequentially performed, to form the third spacer 136 on the second spacer 134. Precisely speaking, the third spacer 136 directly overlays the sidewall of the first spacer 132, so that, the sidewall of the third spacer 136 may be vertical aligned with the vertical portion 134a of the second spacer 134. Accordingly, the first spacer 132, the second spacer 134, and the third spacer 136 together form the spacer structure 130 surrounding the gate structure 110. In other words, the third spacer 136 is formed in a space after removing the dummy spacer 234, so as to maintain the distance R1 from the capping structure 140 to the gate structure 110. Also, the thickness T1 of the capping structure 140 may be precisely controlled through the above-mentioned selective thermal oxidation process P1. In this way, the aspect ratio (T1/T1) between the thickness T1 of the capping structure 140 and the distance R1 from the capping structure 140 to the gate structure 110 will therefore be well-controlled at 1 and 3, preferably at 1.2 to 2.2, but not limited thereto.

Following these, after forming the third spacer 136, a metal silicidation process is performed, to form the metal silicide layer 150 as shown in FIG. 1 on the capping structure 140, and the fabrication of the semiconductor device 10 in the present embodiment is completed. According to the above performances, the aspect ratio between the thickness T1 of a capping structure 140 and the distance R1 from the capping structure 140 to the gate structure 110 is allowable to be well-controlled to prevent a current-intensive regions at two sides of the gate structure 110 from being affected by the capping structure 140 and/or the epitaxial structure 120, thereby improving the electrical performance of the semiconductor device 10, and further improving the operation of the semiconductor device 10.

Through the fabricating method of the semiconductor device 10 in the present embodiment, the thickness T1 of the capping structure 140, as well as the distance R1 from the capping structure 140 to the gate structure 110, are both well-controlled through forming the second capping layer 144 of the capping structure 140, and forming the second spacer 134 of the spacer structure 130 respectively, thereby keeping the aspect ratio between the thickness T1 of the capping structure 140 and the distance R1 from the capping structure 140 to the gate structure 110 at a specific range to improve the electrical performance of the semiconductor device 10.

People skilled in the arts should easily realize the semiconductor device and the fabricating method thereof in the present disclosure is not limited to the aforementioned embodiment, and may further include other examples. The following description will detail the different embodiments of the semiconductor device and the fabricating method thereof in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

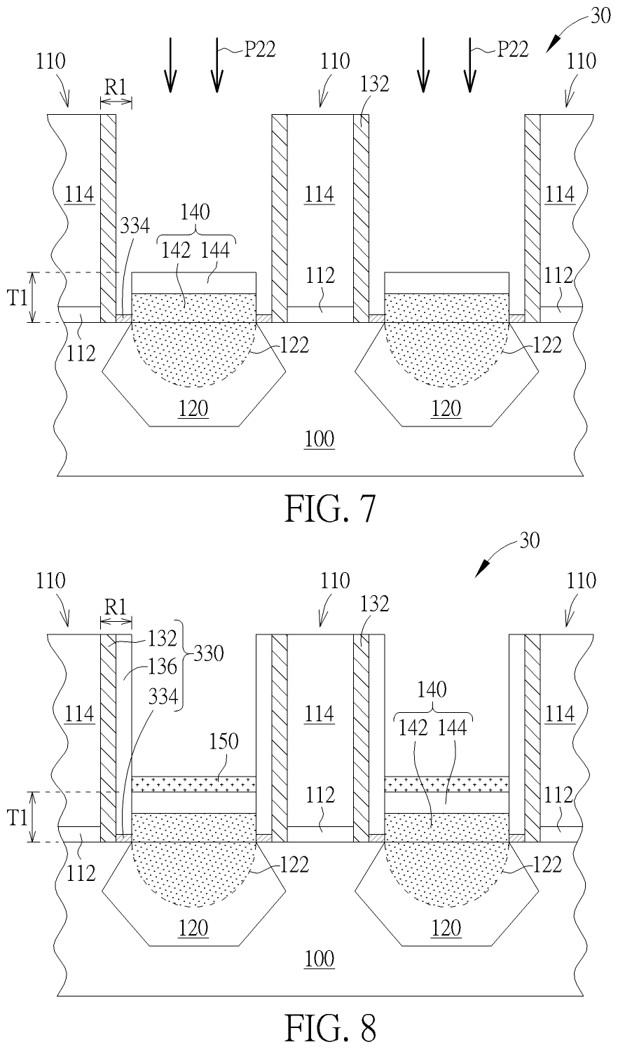

Please refer to FIG. 7 to FIG. 8, which illustrates a semiconductor device 30 according to a second embodiment of the present disclosure. The structure and the fabricating method of the semiconductor device 30 of the present embodiment is substantially the same as that of the aforementioned first embodiment, and all the similarities of the two embodiments will not be redundantly described hereinafter. The difference between the present embodiment and the aforementioned first embodiment is mainly in that a second spacer 334 having a stripe-shaped cross-section is formed.

Precisely speaking, as shown in FIG. 7, while performing at least one etching process P22 on the sacrificial layer 244a, only the dummy spacer 234 overlaying the top surface of the substrate 100 is partially remained through adjusting the etching parameters, to form the second spacer 334 of the present embodiment. The second spacer 334 directly contacts a portion of the sidewall of the capping structure 140. Accordingly, the third spacer 136 formed on the second spacer 334 will therefore directly in contact with another portion of the sidewall of the capping structure 140, as shown in FIG. 8. Then, the first spacer 132, the second spacer 334, and the third spacer 136 together form the spacer structure 330 surrounding the gate structure 110, and the metal silicide layer 150 is next formed on the capping structure 140, after forming the third spacer 136.

Through these performances, the distance R1 from the capping structure 140 to the gate structure 110 can still be well-controlled by forming the second spacer 334 having the stripe-shaped cross-section, thereby keeping the aspect ratio between the thickness T1 of the capping structure 140 and the distance R1 from the capping structure 140 to the gate structure 110 at a specific range for example being about 1 to 3, preferably being about 1.2 to 2.2. In this way, it is sufficient to prevent a current-intensive regions at two sides of the gate structure 110 from being affected by the capping structure 140 and/or the epitaxial structure 120, improving the electrical performance of the semiconductor device 30, and further improving the operation of the semiconductor device 30.

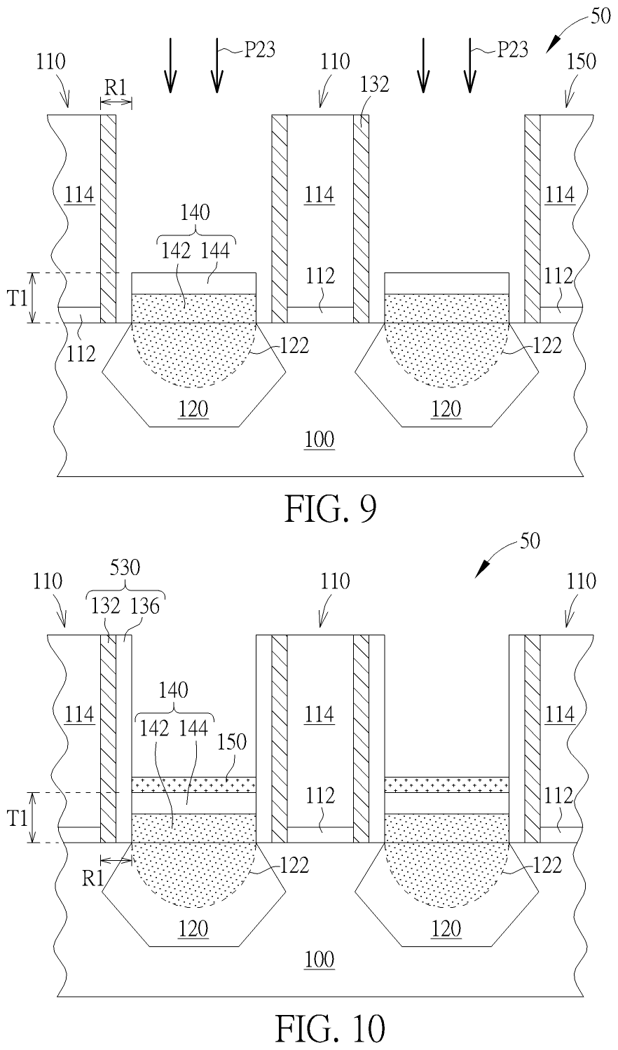

Please refer to FIG. 9 and FIG. 10, which illustrates a semiconductor device 50 according to a third embodiment of the present disclosure. The structure and the fabricating method of the semiconductor device 50 of the present embodiment is substantially the same as that of the aforementioned first embodiment, and all the similarities of the two embodiments will not be redundantly described hereinafter. The difference between the present embodiment and the aforementioned first embodiment is mainly in that the formation of the second spacer has been omitted in the present embodiment.

Precisely speaking, as shown in FIG. 9, while performing at least one etching process P23 on the sacrificial layer 244a, the dummy spacer 234 is completely removed through adjusting the etching parameters. Following these, as shown in FIG. 10, the third spacer 136 formed subsequently is formed in the spacer after removing the dummy spacer 234, thereby still maintaining the distance from the capping structure 140 to the gate structure 110. In other words, only the first spacer 132 and the third spacer 136 are formed in the present embodiment, and the third spacer 136 directly in contact with the entire sidewall of the capping structure 140. Accordingly, the first spacer 132 and the third spacer 136 together form a spacer structure 530 surrounding each of the gate structures 110, and the metal silicide layer 150 is next formed on the capping structure 140, after forming the third spacer 136.

Through these performances, the distance R1 from the capping structure 140 to the gate structure 110 is previously defined by forming the dummy spacer 234 on the sidewall of the gate structure 110, before forming the capping structure 140. Then, after forming the capping structure 140, the dummy spacer 234 is completely removed. Accordingly, the fabricating method of the present embodiment still enables to keep the aspect ratio between the thickness T1 of the capping structure 140 and the distance R1 from the capping structure 140 to the gate structure 110 at a specific range for example being about 1 to 3, preferably being about 1.2 to 2.2. In this way, it is sufficient to prevent a current-intensive regions at two sides of the gate structure 110 from being affected by the capping structure 140 and/or the epitaxial structure 120, improving the electrical performance of the semiconductor device 50, and further improving the operation of the semiconductor device 50.

Overall speaking, according to the semiconductor device of the present disclosure, a second spacer is arranged between the gate structure and the capping structure and/or the epitaxial structure, to at least partially contact the capping structure, such that, the aspect ratio between the thickness of the capping structure and the distance from the capping structure to the gate structure will be precisely controlled, to prevent a current-intensive regions at two sides of the gate structure from being affected by the capping structure and/or the epitaxial structure, thereby improving the electrical performance of the semiconductor device, and further improving the operation of the semiconductor device. Through these arrangements, the semiconductor device of the present disclosure is allowable to be put in use on any functional semiconductor device including the epitaxial structure, such as a MOS transistor device or a SRAM device, but not limited thereto.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
two gate structures disposed on the substrate;
a spacer structure disposed on the substrate and surrounding each of the gate structures;
an epitaxial structure disposed in the substrate, between the two gate structures;
a capping structure disposed on the epitaxial structure, between the two gate structures; and
a metal silicide layer, disposed on the capping structure;
wherein the spacer structure comprises a first spacer, a second spacer and a third spacer stacked sequentially on a sidewall of each of the gate structures, and the second spacer at least contacts a portion of a sidewall of the capping structure.

2. The semiconductor device according to claim 1, wherein the second spacer comprises a L-shaped cross-section, and a vertical portion of the L-shaped cross-section overlays a whole sidewall of the capping structure and a horizontal portion of the L-shaped cross-section is disposed on a top surface of the substrate.

3. The semiconductor device according to claim 1, wherein the second spacer comprises a stripe-shaped cross-section disposed on a top surface of the substrate.

4. The semiconductor device according to claim 3, wherein the third spacer overlays another portion of the sidewall of the capping structure.

5. The semiconductor device according to claim 1, wherein the second spacer comprises a material different from materials of the first spacer and the third spacer.

6. The semiconductor device according to claim 1, wherein an aspect ratio between a thickness of the capping structure and a minimum distance from the capping structure to one of the two gate structures is 1.2 to 2.2.

7. The semiconductor device according to claim 1, wherein the capping structure comprises a first capping layer and a second capping layer stacked sequentially on the epitaxial structure.

8. The semiconductor device according to claim 7, wherein the second capping layer comprises a thickness between 130 angstroms to 210 angstroms.

9. The semiconductor device according to claim 1, wherein the semiconductor device comprises a static random access memory device.

10. A method of forming a semiconductor device, comprising:
providing a substrate;
forming two gate structures on the substrate;
sequentially forming a first spacer and a dummy spacer on the substrate, to surround the two gate structures;
forming an epitaxial structure in the substrate, between the two gate structures;
forming a capping structure on the epitaxial structure, between the two gate structures, the capping structure comprising a first capping layer and a second capping layer stacked sequentially on the epitaxial structure; and
forming a metal silicide layer on the capping structure;
wherein forming the capping structure further comprising:
forming the first capping layer;
forming a capping material layer on the first capping layer;
oxidizing a portion of the capping material layer; and
removing an oxidized portion of the capping material layer, to form the second capping layer stacked on the first capping layer.

11. The method of fabricating the semiconductor device according to claim 10, wherein a thickness of the second capping layer is smaller than a thickness of the capping material layer.

12. The method of fabricating the semiconductor device according to claim 11, wherein a thickness of the oxidized portion is between 10 angstroms to 40 angstroms, and the thickness of the capping material layer is between 140 angstroms to 250 angstroms.

13. The method of fabricating the semiconductor device according to claim 10, wherein the epitaxial structure is formed after forming the first spacer, and the first capping layer is formed after forming the dummy spacer.

14. The method of fabricating the semiconductor device according to claim 10, further comprising:
after oxidizing the portion of the capping material layer, completely removing the dummy spacer; and
forming a third spacer surrounding the first spacer and each of the gate structures, wherein the metal silicide layer is formed after forming the third spacer.

15. The method of fabricating the semiconductor device according to claim 10, further comprising:
after oxidizing the portion of the capping material layer, partially removing the dummy spacer while removing the oxidized portion of the capping material layer, to form a second spacer, wherein the second spacer at least contacts a portion of a sidewall of the capping structure; and
forming a third spacer directly on the second spacer, wherein the metal silicide layer is formed after forming the third spacer.

16. The method of fabricating the semiconductor device according to claim 15, wherein the second spacer comprises a L-shaped cross-section or a stripe-shaped cross-section.

17. The method of fabricating the semiconductor device according to claim 10, oxidizing the portion of the capping material layer by performing a rapid thermal oxidation process.

18. The method of fabricating the semiconductor device according to claim 10, wherein an aspect ratio between a thickness of the capping structure and a minimum distance from the capping structure to one of the two gate structures is 1.2 to 2.2.
